(19) United States
(12) Patent Application Publication
(10) Pub. No.: US 2026/0161837 A1
(43) Pub. Date: Jun. 11, 2026

(54) REALISTIC RECONSTRUCTION OF REAL SPACES USING SPATIAL SCHEMA AS A MEDIUM

(71) Applicants: Korea University Research and Business Foundation, Seoul (KR); TeeLabs Co., Ltd., Seoul (KR)

(72) Inventors: Nak Ju DOH, Seoul (KR); Hyung A CHOI, Seoul (KR); Bum Chul JANG, Seoul (KR)

(73) Assignees: Korea University Research and Business Foundation, Seoul (KR); TeeLabs Co., Ltd., Seoul (KR)

(21) Appl. No.: 19/181,286

(22) Filed: Apr. 16, 2025

(30) Foreign Application Priority Data
May 20, 2024 (KR) 10-2024-0065392

(51) Int. Cl. G06F 30/13

(52) U.S. Cl. CPC G06F 30/13

(57) ABSTRACT

Disclosed are a method and an apparatus for realistic reconstruction of a real space using a spatial schema as a medium. An apparatus for construction of a digital space model using a spatial schema as a medium includes: a spatial schema generation module configured to generate a spatial schema encoded as a descriptive expression of a target space, which is an object for constructing a digital space model; a space information database configured to store space information including image data of the target space; and an automatic generation network module configured to receive the spatial schema as input, and automatically construct a digital space model corresponding to the spatial schema based on the spatial schema and the space information stored in the space information database using a model trained to generate a digital space model.

### CROSS-REFERENCE TO RELATED APPLICATION

This application claims priority to and the benefit of Korean Patent Application No. 10-2024-0065392, filed on May 20, 2024, the disclosure of which is incorporated herein by reference in its entirety.

### BACKGROUND OF THE INVENTION

### 1. Field of the Invention

The present invention relates to realistic reconstruction of real spaces, more particularly, to a system for acquiring space information including image information through a variety of sensor systems in a real space and for reconstruction of the real space in a digital model.

### 2. Description of the Related Art

A digital model for space may exist in different forms. For example, the digital model may be a three-dimensional (3D) digital space model for reconstruction of a real space. In this regard, the 3D digital space model or the digital space model refers to overall restoration of image information and depth information of the real space.

For realistic reconstruction of a real space, location determination technology is required. Through various sensors for scanning a real space, sensor data may be acquired. The location determination technology is a technique to determine an exact position at which the sensor data is acquired, and to align different sensor information into a single standard based on the corresponding information.

A reason requiring such location determination technology is that all information cannot be obtained on one site of indoor or outdoor space without movement of a sensor, therefore, sensor data should be obtained at multiple positions.

The purpose of constructing a digital space model is to similarly restore (or reconstruct) image information of real environments and a ratio of geographical features of a real space. Therefore, through the digital space model, it is possible to embody various extensions, including metaverse, XR contents, digital twin realization, architectural surveying, real estate, space promotion, robot simulation, AI learning data, or the like, which are associated with the real space. Accordingly, there is a need for a method for construction of a digital space model that is capable of various extensions and applications.

Further, in order to construct such a digital space model using large-scale data obtained by scanning or measuring a real space, some problems such as complexity of the space to be subjected and operation (or computation) quantity required therefor may be involved.

### PRIOR ART LITERATURE

### Patent Literature

Korean Patent Laid-Open Publication No. 10-2019-0117354 (entitled: Method and apparatus for generating 3D map of indoor space)

Korean Patent Laid-Open Publication No. 10-2016-0132153 (entitled: Method of extracting outer space feature information)

### SUMMARY OF THE INVENTION

### Technical Problem

Therefore, it is an object of the present invention to provide an automatic construction system of a digital space model using a spatial schema as a medium by way of embodiments.

### Technical Solution

A digital space model construction apparatus using a spatial schema as a medium according to an embodiment of the present invention, may include: a spatial schema generation module to generate a spatial schema encoded as a descriptive expression relating to a target space, which is an object for constructing a digital space model; a space information database configured to store space information including image data of the target space; and an automatic generation network module configured to receive the spatial schema as input, and automatically construct a digital space model corresponding to the spatial schema based on the spatial schema and the space information stored in the space information database using a model trained to generate a digital space model.

The target space may be a physical space existing in the real world, and the digital space model may be a three-dimensional digital space model capable of representing image information and depth information relating to the target space at any arbitrary pose.

The spatial schema is information encoded based on physical commonalities of components in the target space.

The apparatus according to another embodiment may further include a structure/object classifier configured to classify the components of the target space into the structure and the object and to generate structure information related to the structure and object information related to the object.

The spatial schema generation module may be configured to: generate a structure schema encoded as a descriptive expression of the structure information based on at least one of a geometry of the structure information, a texture associated with the geometry, and interrelation among the geometries; and generate an object schema encoded as a descriptive expression of the object information based on at least one of physical commonalities, interrelation and interdependency of the object information.

The automatic generation network module may receive the structure schema and object schema as input, select an object model in the space information database based on the object schema, and automatically construct a digital space model based on the structure schema, the space information and the object model through the trained model.

The apparatus according to another embodiment may further include: a space information acquiring module configured to obtain raw sensor data including image information of a target space existing in the real world; and a space information alignment module configured to align the raw sensor data obtained in multiple positions based on a reference coordinate system so as to generate aligned sensor information.

The raw sensor data may be acquired in a static manner, where the module is fixed to a tripod or the like at k−1 point and k point moved from k−1 point and acquires the data while rotating, or in a dynamic manner, where the module acquires the data while moving from k−1 point to k point.

The space information alignment module may generate the aligned sensor information through probability-based coordinate relation prediction of the raw sensor data and feature-based correction.

The apparatus according to another embodiment may further include a modification request input module to receive modification information requesting modification of a component in the digital space model.

The automatic generation network module may re-generate a digital space model based on the modification information.

The automatic generation network module may dispose the selected object model in the digital space model based on at least one of position information encoded in the object schema, interrelation information with surrounding environments and attribute information. At this time, the attribute information of the object model is adjustable.

The automatic generation network module may provide the object schema to an external modeling system or scanning device if an object model having a real-world identity to the object information encoded in the object schema that is not less than a standard value does not exist in the space information database.

The model trained to generate the digital space model is a large-scale space model trained through: a first network generation process that receives raw sensor data including image information of a real space as input and learns to generate a spatial schema encoded with physical features of the real space through descriptive expression; a second network generation process that learns to select a digital space information based on the spatial schema; and a third network generation process that learns to generate a digital space model based on the spatial schema and the selected space information.

The third network may learn to classify the components included in the space information into a structure and an object, generate structure information related to the structure, and generate a digital space model based on the spatial schema for the structure information.

A method for constructing a digital space model using a spatial schema as a medium according to one embodiment of the present invention may include: generating a spatial schema encoded as a descriptive expression of a target space, which is an object for constructing a digital space model; constructing database storing space information including image data for the target space; receiving the spatial schema as input; and automatically constructing a digital space model corresponding to the spatial schema, based on the spatial schema and the space information stored in the space information database using a model trained to generate the digital space model.

A method for constructing a digital space model using a spatial schema as a medium according to another embodiment of the present invention is a method for constructing a three-dimensional digital space model that can represent image information and depth information of a target space at any arbitrary pose, wherein the target space physically exists in the real world, and may include: classifying components in the target space into a structure and an object, and, generating structure information related to the structure and object information related to the object; generating a structure schema encoded as a descriptive expression of the structure information based on any one of physical commonalities, interrelation and interdependency of the structure information; generating an object schema encoded as a descriptive expression of the object information based on any one of physical commonalities, interrelation and interdependency of the object information; receiving the structure schema and the object schema as input, and selecting an object model in the space information database based on the object schema; and receiving the structure schema, the space information and the object model as input, and automatically constructing a digital space model of the target space using a model trained to generate the digital space model.

### Effect of Invention

According to the embodiments of the present invention, a digital space model can be automatically constructed through a spatial schema as a medium.

In this regard, a network with trained sufficient data may also automatically re-construct a space, thereby attaining an advantage of automatically performing all processes except for acquisition of sensor data.

Further, according to the method of re-constructing a space by a network through bottom-up approach based on a spatial schema it is possible to construct a realistic digital model completely automatized using a schema as a medium.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates the configuration of a digital space model construction apparatus according to a first embodiment of the present invention.

FIG. 2 illustrates a target space.

FIG. 3 illustrates the configuration of a space information database shown in FIG. 1.

FIG. 4 illustrates the configuration of a digital space model construction apparatus according to a second embodiment of the present invention.

FIG. 5 shows geometry information as an example of the space information in an exemplary target space.

FIG. 6 illustrates an example of geometry information on a structure of a real space, while FIG. 7 illustrates characteristics of the geometry information of an object.

FIGS. 8 and 9 illustrate different standards for classification of structure and object.

FIG. 10 shows examples of object models included in an object model database of the space information database shown in FIG. 3.

FIG. 11 illustrates the configuration of a digital space model construction apparatus according to a third embodiment of the present invention.

FIGS. 12A to 12C show examples of various devices for acquisition of raw sensor data shown in FIG. 11.

FIG. 13 illustrates the static type scanning exemplified in FIGS. 12A to 12C, while FIG. 14 illustrates the dynamic type scanning exemplified in FIGS. 12A to 12C.

FIG. 15 shows an example of prediction through probability distribution, while FIG. 16 illustrates an example of correction in FIG. 13 or 14.

FIG. 17 illustrates the configuration of a digital space model construction apparatus according to a fourth embodiment of the present invention.

FIG. 18 illustrates a process of constructing a digital space model generation network according to the embodiment of the present invention.

### DETAILED DESCRIPTION FOR CARRYING OUT INVENTION

Specific structural and functional descriptions are merely illustrative for the purpose of explaining the embodiments according to the concept of the present disclosure. Furthermore, the embodiments according to the concept of the present disclosure can be implemented in various forms and the present disclosure is not limited to the embodiments described herein.

The embodiments according to the concept of the present disclosure may be implemented in various forms as various modifications may be made. The embodiments will be described in detail herein with reference to the drawings. However, it should be understood that the present disclosure is not limited to the embodiments according to the concept of the present disclosure, but includes changes, equivalents, or alternatives falling within the spirit and scope of the present disclosure.

The terms such as “first” and “second” are used herein merely to describe a variety of constituent elements, but the constituent elements are not limited by the terms. The terms are used only for the purpose of distinguishing one constituent element from another constituent element. For example, a first element may be termed a second element and a second element may be termed a first element without departing from the scope of rights according to the concept of the present disclosure.

It will be understood that when an element is referred to as being “on”, “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Other words used to describe the relationship between elements should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” in the specification should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure will now be described more fully with reference to the accompanying drawings, in which exemplary embodiments of the disclosure are shown. This disclosure may, however, be embodied in many different forms and should not be construed as limited to the exemplary embodiments set forth herein. Like reference numerals in the drawings denote like elements.

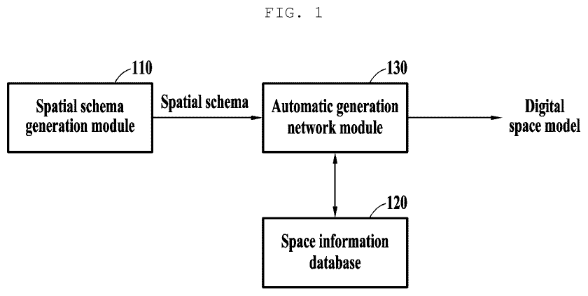

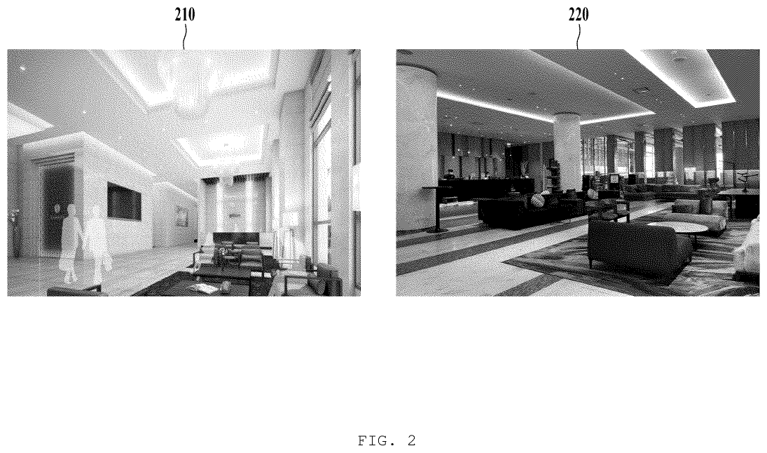

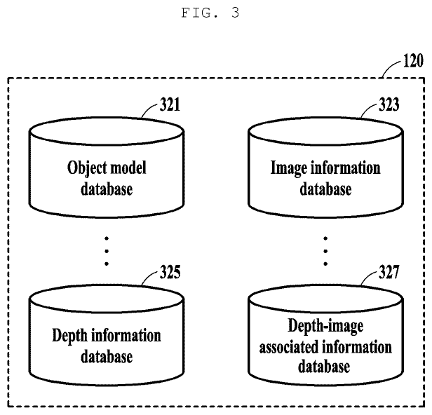

FIG. 1 is a figure illustrating the configuration of a digital space model construction apparatus according to a first embodiment of the present invention, while FIG. 2 illustrates a target space.

Referring to FIG. 1, the digital space model construction apparatus may include a spatial schema generation module 110, a space information database 120 and an automatic generation network module 130.

The spatial schema generation module 110 may include a processor configured to generate a spatial schema for space. Further, the spatial schema generation module 110 may include a processor configured to generate the spatial schema from geometry information of a target space. Further, the spatial schema generation module 110 may receive geometry information, image information and depth information on the target space as input, and generate the spatial schema using a model or network trained to generate the spatial schema based on the geometry information, image information and depth information.

The spatial schema generation module 110 may generate a spatial schema encoded as a descriptive expression of a target space as a subject for construction of a digital space model.

The ‘space’ or ‘target space’ may be a virtual space or a physical space existing in the real world. Further, the digital space model means a three-dimensional digital space model that can represent image information and depth information on the target space at any arbitrary pose.

The ‘spatial schema’ means encoded information in which physical information of the target space is sufficiently carried. Further, the ‘spatial schema’ may be information encoded as a descriptive expression corresponding to human language, machine code, or human language and machine code. For example, the spatial schema may include mesh expression, geometry-image interrelation, point cloud data expression, coordinate, topology, geometry, texture information associated with the geometry, interrelation among geometries, or the like in the target space.

The spatial schema is information that can be automatically extracted by applying various algorithms to ‘raw sensor data’, which is information acquired from various sensors for scanning the target space, and that carries sufficient features of the space.

Additional explanation and illustration for the spatial schema would be further described by way of different embodiments in the present specification.

The space information database 120 may include at least one memory for storing space information.

The space information database 120 stores the space information including image data of the target space. The ‘space information’ may include raw sensor data and various object models.

The automatic generation network module 130 may include a processor configured to receive the spatial schema as input, and automatically construct a digital space model corresponding to the spatial schema.

The automatic generation network module 130 may re-construct the target space based on the spatial schema and the space information stored in the space information database using a model trained to generate the digital space model.

The ‘automatic generation network module’ in the present specification may also be called an ‘automatic model generation network module’.

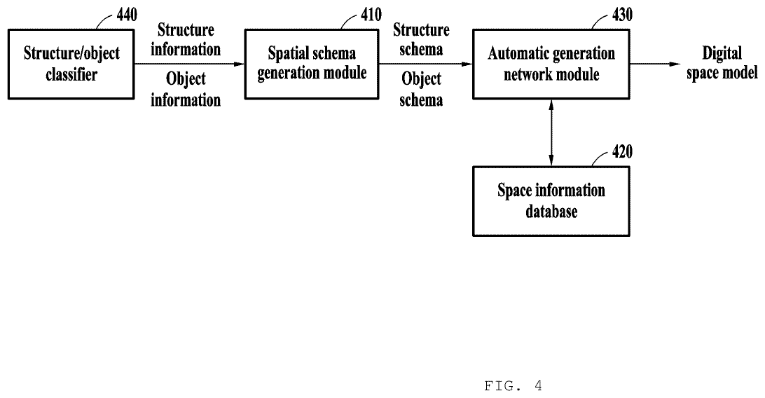

FIG. 3 is a figure explaining the configuration of the space information database illustrated in FIG. 1.

The space information database 120 may store information on various object models as well as the information of the target space as a subject of reconstruction.

The space information database 120 may include: an object model database 321 for storing various object models; an image information database 323 for storing the image information scanned through a sensor; a depth information database 325 for storing depth information acquired through a depth measuring sensor; and a depth-image associated information database 327 that stores information associated with the image information and depth information.

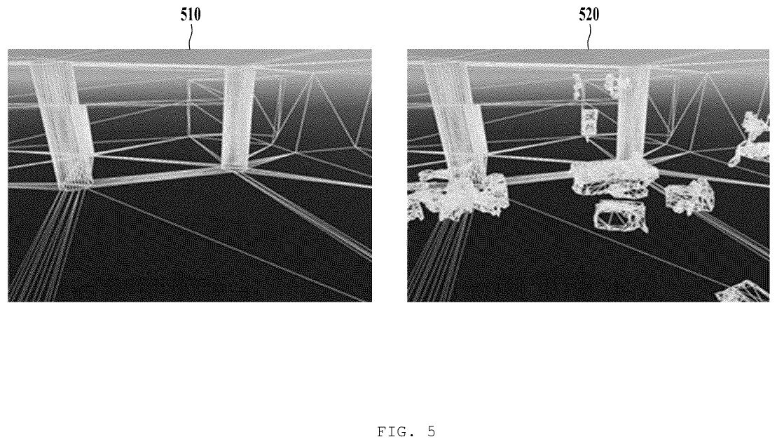

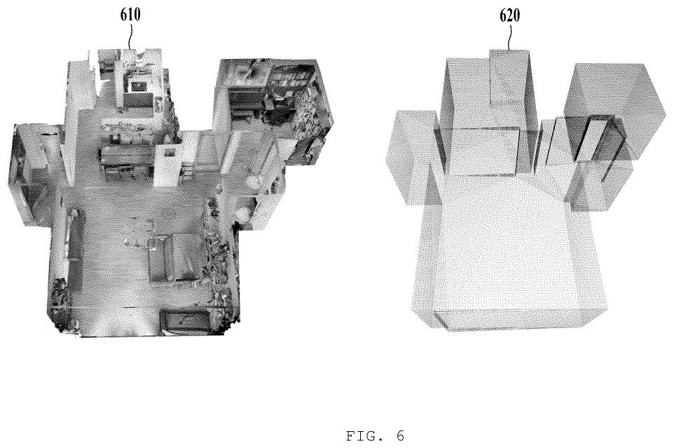

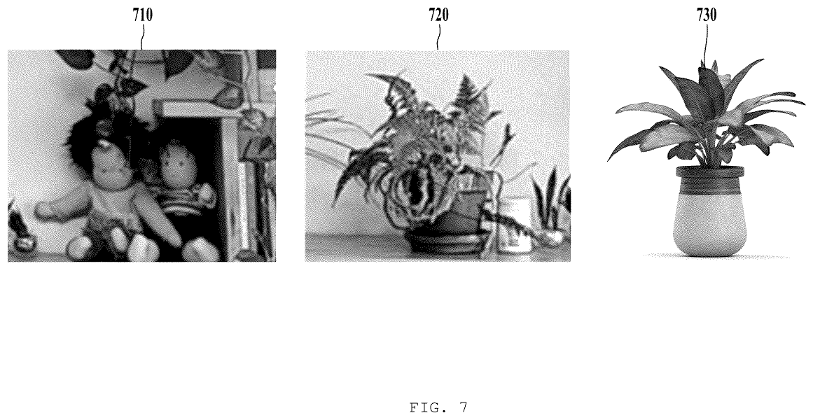

FIG. 4 is a figure explaining the configuration of a digital space model construction apparatus according to a second embodiment of the present invention, while FIG. 5 shows geometry information as an example of the space information in an exemplary target space. Further, FIG. 6 is a figure explaining an example of the geometry information on a structure in a real space, while FIG. 7 is a figure illustrating features of geometry information of an object.

Hereinafter, with reference to FIGS. 4 to 7, the second embodiment of the present invention will be described.

Referring to FIG. 4, the digital space model construction apparatus may include a spatial schema generation module 410, a space information database 420, an automatic generation network module 430 and a structure/object classifier 440.

The structure/object classifier 440 may include a processor configured to classify components of a target space into a structure and an object in raw sensor data of the target space and to generate structure information related to the structure and object information related to the object. A method for classification or separation of a structure and an object may be performed through various algorithms such as a method of extracting outer space feature information, disclosed in the prior art literature, that is, Korean Patent Laid-Open Publication No. 10-2016-0132153, or a density-based clustering method. Further, the structure/object classifier 440 may classify components of the target space into a structure and an object through a learned model or network, and then, generate structure information related to the structure and object information related to the object.

The ‘object’ means all portions except for the structure. For example, in the virtual space 210 or the space 220 existing in the real world illustrated in FIG. 2, the structure refers to the components constructed or installed in the space for the purpose of semi-permanent use.

The geometry regarding the structure in a target space may be abbreviated and expressed on the basis of physical features. At this time, the abbreviated expression of the structure has an amount of information considerably lower than a volume or area occupying in the target space.

For example, if no object exists in the target space, the abbreviated information on the structure may be represented through coordinate information, polygon information, vector information, mesh information, or the like. As a more specific example, FIG. 5 may be referred.

Referring to FIG. 5, the geometry expression 510 of the structure to the real space 220 existing in the real world may be represented in the form of lines to illustrate the structure. At this time, the geometry expression representing all components included in the real space 220 may include information of the structure and object. As shown in FIG. 5, when the geometry information on the object is included, a volume represented in the space is slightly increased, however, it can be confirmed that remarkably much information for representing the space geometry may be added.

Referring to FIG. 6, the geometry expression 620 on a structure of the indoor space 610 may be represented with considerably less information compared to the volume. That is, the structure may be represented with abbreviated information such as line, surface, a length of line, area, a connection between lines, and a connection between surfaces.

However, as shown in FIG. 7, in the case of real objects (710, 720), since these have complex geometry information, much more information relative to a volume or area of the object is required for geometry expression as compared to the structure.

Further, even in the case of a virtually generated object model 730 other than the real objects (710, 720), although the geometry expression is possible with less information than the real objects (710, 720), exceptionally much information is required as compared to the structure.

For the object, for example, a desk, a chair, electronics, office supplies and/or a handbasin, an amount of information required for modeling relative to occupying volume is generally and markedly much more compared to the structure. The structure may include, for example, wall, ceil, floor, glass window frame, door, built-in furniture, etc., and an amount of information required for modeling relative to volume is considerably small as compared to the object.

Again, referring to FIG. 4, the spatial schema generation module 410 may generate a spatial schema based on the structure information and the object information. Further, the spatial schema generation module 410 may implement the same function as the spatial schema generation module 110 shown in FIG. 1.

The ‘spatial schema’ means encoded information sufficiently carrying physical information of the target space, therefore, may be a concept that includes the structure schema encoded as a descriptive expression of the structure information, as well as the object schema encoded as a descriptive expression of the object information.

The ‘structure information’ may include a variety of physical information, for example, geometry information and/or texture information of the structure, etc. On the other hand, the ‘object information’ may include a variety of information such as geometry information and/or texture information of the object, etc. in order to determine whether there is any object similar to the object in the real space in the space information database.

The spatial schema generation module 410 may generate a structure schema of the structure information based on at least any one among geometry of the structure information, texture associated with to the geometry and interrelation among the geometries.

The spatial schema generation module 410 may generate an object schema of the object information based on at least any one among physical commonalities, interrelation and inter-dependency of the object information.

The structure schema may consist of geometry of the structure, texture associated with the geometry, interrelation among geometries, etc. For example, with regard to a wall, floor or ceil, these are included in a common physical surface and are configured in a direction of viewing an observer, therefore, can be represented through a plane (or a flat surface) patch and a vertical direction vector of the corresponding plane.

The texture associated with the geometry may be a tile type to form the corresponding plane, wherein texture information on all regions of the plane may be stored or a representative texture only may be stored (in the case of repeated tiles).

The interrelation or inter-dependency between geometries may be an expression of more macroscopic space such as room, corridor, hall, etc. in the target space through a combination of the corresponding planes. Further, in the case of the structure such as door or window, movement or rotation information may also be included.

The object schema may include, for example, type of individual object, position of the object, attribute of the object, optical features, a relationship between objects, or the like. The optical features of the object may be a descriptive schema such as reflection, luminescence, transmission, etc., and may improve realistic effects by applying the corresponding information to rendering of a digital model.

The interrelation or inter-dependency between objects may be a schema in regard to a relationship between a specific object and another object(s), more specifically, such a schema that a monitor ‘is present on’ a desk, a telephone ‘is inserted into’ a charger terminal, etc. As shown in the latter example, a specific schema may be deduced from circumstances and designated.

The structure schema, object schema and spatial schema may be described by schema symbols such as XML, JSON, X3D, etc., may be represented according to a modeling technique such as UML, or may be stated by a method specialized according to separate methods of embodiment.

The space information database 420 may be the same database structure as the space information database 120 shown in FIG. 3.

The automatic generation network module 430 may execute the same function as the automatic generation network module 130 shown in FIG. 1. Further, the automatic generation network module 430 is a network configured to receive the structure schema and the object schema as input, and construct a digital space model. In this regard, in the case of an object, the automatic generation network module 430 may select an object with high similarity to the object placed in the target space using the object schema and the space information database 420.

Therefore, the automatic generation network module 430 may select an object model in the space information database 420 based on the object schema, and may automatically construct a digital space model based on the structure schema, the space information and the object model through a learned model.

The automatic generation network module 430 is in the form of artificial intelligence network that has finished preliminary training, and has already been trained to generate a specific digital space model relating to the input of given structure schema and object schema. If sufficient training was repeated, the automatic generation network module 430 is characterized in that, if a structure schema, an object schema, or both of these schemas are simultaneously given, this module can automatically generate a digital space model.

Herein, when a space subjected to digital space model construction consists of only a structure, the structure schema may be applied to the automatic generation network module 430 while an object schema is regarded to be empty since the object refers to all portions except for the structure.

To provide similar image information and depth information at the same pose and field of view within a target space and digital space model desired for digital expression may be represented as ‘the real-world identity is high’. At this time, if dynamic elements are included, a door or window or a position of an object or interrelation between objects is changed, or illuminant features of the object or surrounding illuminant features are varied, the real-world identity may be lowered.

The automatic generation network module 430 may select an object model similar to the object encoded in the object schema in terms of type, size or attribute thereof in the object model database 321. The automatic generation network module 430 may dispose the selected object in the digital space model and adjust the attribute thereof by reflecting the position, interrelation or attribute encoded in the object schema. For example, a desk, chair, illumination, faucet, electronics, etc. may be selected in the object model database 321 or the like in a way of improving the real-world identity. Further, by reflecting the brightness of the illumination or conditions of the electronics, lighting attribute of the illumination may be adjusted to be ‘turn on’ or TV screen condition may be adjusted to be ‘turn off’.

Since a model of each object and attribute thereof have been applied to the generated digital space model, there is an advantage in that, when it is further connected to robot simulation or metaverse, etc., static attribute such as the position or direction of an object, as well as dynamic attribute such as a variation in TV screen, drainage of a faucet, etc. can be additionally represented. Further, any object or structure not present in the target space may be freely added to the generated digital space model, or any variation may be randomly applied to various objects already existing or newly added to the space so as to represent a variety of space environments.

If an object model with more than standard value of real-world identity to the object information encoded in the object schema does not exist in the space information database 420, the automatic generation network module 430 may conduct various applications, for example, may select an object with relatively higher similarity to the corresponding object, directly carry out modeling of an object in the real space using alternative techniques, or utilize a model having high real-world identity in another database by adding an object model database 321, or the like.

For example, if antiquities in a museum do not exist in the object model database 321, the corresponding model is prepared by an alternative object-exclusive modeling scanner and algorithm and the digital space model may be re-generated or amended and revised while reflecting additional information.

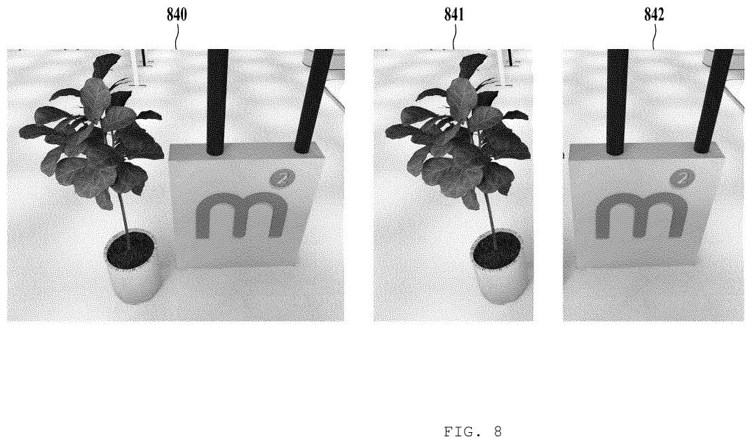

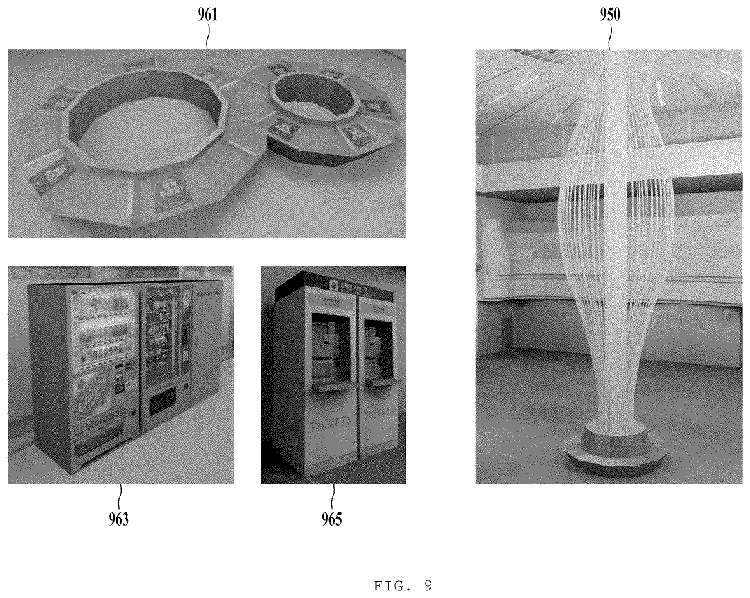

FIGS. 8 and 9 are figures explaining different standards for classifying (or distinguishing) a structure and an object.

Referring to FIG. 8, unlike typical structures, there are components that can be classified into an object or structure according to the point of view. For example, for a flowerpot 841 in the space 840, it is obviously an object. However, an interior part 842 connected to a structure may be classified into the object or the structure. As such, a component capable of being classified into an object or a structure may also be optionally (or arbitrarily) classified through algorithm or by a user.

Further, referring to FIG. 9, the component 950 capable of being represented with geometry primitive expression such as polygon or spline may be classified into a structure. Similarly, although having a feature of object, some components (961, 963, 965) possibly represented with geometry primitive expression such as polygon or box may also be classified into structures or objects according to the choice of user.

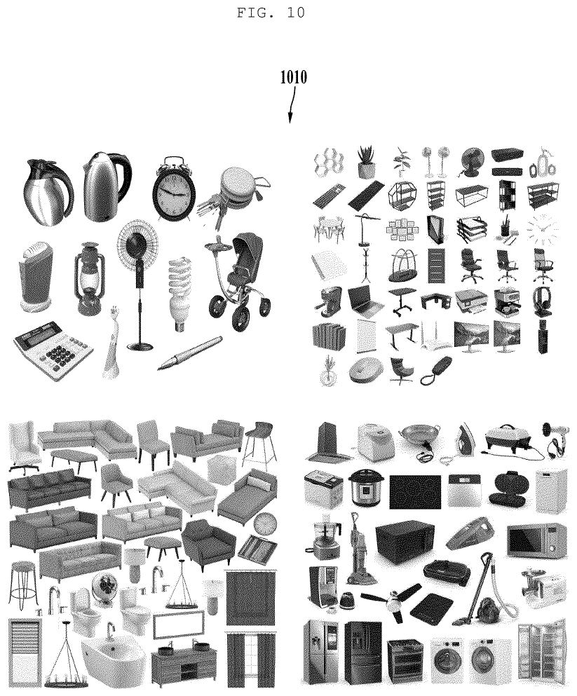

FIG. 10 is a figure illustrating examples of the object models included in the object model database of the space information database shown in FIG. 3.

Referring to FIG. 10, the object model stored in the object model database 321 may be a third-dimensional digital model of various objects. The 3D digital model may collect virtually prepared ones in the form of database, or may be a collection of modeling result(s) in different methods in the real space.

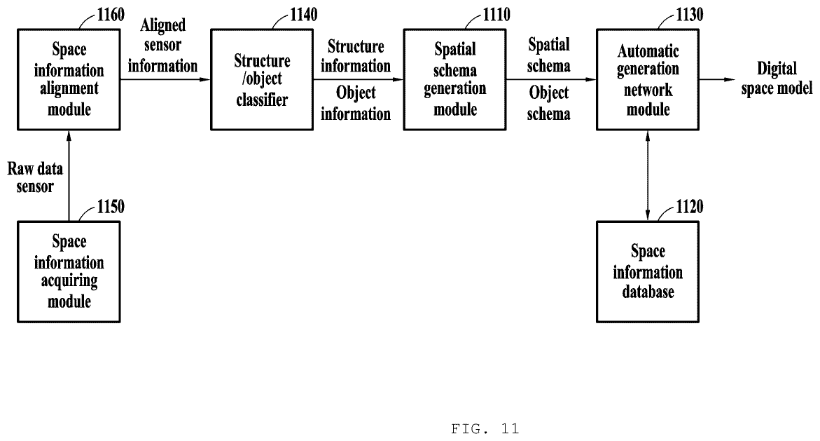

FIG. 11 is a figure illustrating the configuration of a digital space model constructing apparatus according to a third embodiment of the present invention.

Referring to FIG. 11, the digital space model constructing apparatus may include a space information acquiring module 1150, a space information alignment module 1160, a structure/object classifier 1140, a spatial schema generation module 1110, a space information database 1120 and an automatic generation network module 1130.

The space information acquiring module 1150 acquires raw sensor data including image information on a target space existing in the real world.

The space information acquiring module 1150 utilizes a sensor system including an image acquiring sensor and thus may acquire sensor information at multiple positions within a wider target space than an angle of view and a viewing range at which the sensor can obtain sufficient information.

The sensor system may include, for example, LiDAR, RADAR, ToF sensor for acquiring depth information, including an image acquiring device; IMU, accelerometer, geomagnetic field, etc. for acquiring inertial information. The sensor system may gather all information acquired in the target space to generate raw sensor information.

The space information alignment module 1160 may align the raw sensor data acquired at multiple positions based on a reference coordinate system and generate aligned sensor information.

The structure/object classifier 1140 may conduct the same function as the structure/object classifier 440 shown in FIG. 4.

The spatial schema generation module 1110 may conduct the same function as the spatial schema generation module 410 shown in FIG. 4.

The space information database 1120 may conduct the same function as the space information database 420 shown in FIG. 4.

The automatic generation network module 1130 may conduct the same function as the automatic generation network module 430 shown in FIG. 4.

Meanwhile, generation of a digital space model by the automatic generation network module 1130 may proceed in a batch form for all data after completing the collection of space information. Further, the generation of a digital space model may also proceed along with acquiring the space information at the same time or sequentially. Further, a process of alignment of the space information, separation of structure and object, generation of a spatial schema, or generation of a digital space model may proceed while skipping some of processes or integrating the same depending on the configuration of algorithm or if it is necessary after acquiring the space information.

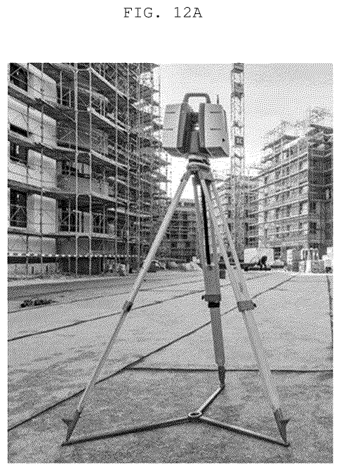

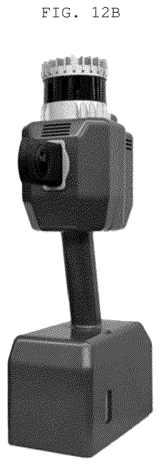

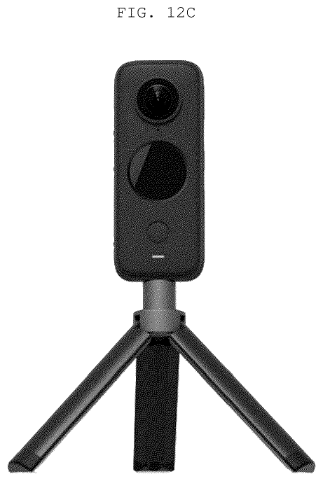

FIGS. 12A to 12C are figures illustrating examples of various apparatuses for acquiring raw sensor data shown in FIG. 11.

Referring to FIGS. 12A to 12C, FIG. 12A illustrates a static space scanner (e.g., ScanStation P50 manufactured by Leica Co.) utilized for gathering static space information, FIG. 12B illustrates a dynamic space scanner (e.g., TeeScanner manufactured by TeeLabs Co.) utilized for gathering dynamic space information, and FIG. 12C illustrates 360 degree camera (ONE X2 manufactured by Instar 360 Co.) utilized for gathering image information included in the static space information and dynamic space information.

Specifically, the static space scanner is a device that acquires space information by fitting a space scanner on the ground using generally a tripod or stand, and may be classified into a static interval acquisition space scanner and a static instant acquisition space scanner.

The static interval acquisition space scanner may acquire space information while rotating a scanner after fitting the scanner on the ground, so that a data acquisition time may be extended. On the other hand, the static instant acquisition space scanner is a device to instantly acquire space information after fitting a scanner on the ground, so that a data acquisition time may be shortened.

The static interval acquisition space scanner may include, for example, a terrestrial laser scanner system (TLS) and ScanStation P50 manufactured by Leica Co., or the like. On the other hand, the static instant acquisition space scanner may include, for example, 360 degrees camera that acquires a single picture at one time.

The static space scanner may acquire space information in only a region where a support can be mounted as the support such as a tripod is fitted on the ground. Since space information is acquired in only a location where the scanner is installed, the space information may be discontinuously obtained. The static space scanner may acquire space information by repeating the processes of fitting the scanner, acquiring space information, moving and re-fitting the scanner.

The dynamic space scanner is generally a device to move and acquire space information, which is carried on a hand, shoulder or back of a person, or mounted on a mobile robot, automobile, drone, etc., and may acquire space information while the person or object moves.

For example, the dynamic space scanner may include a hand-held type space scanner such as a mobile mapping system (MMS) and TeeScanner manufactured by TeeLabs Co.

The hand-held type dynamic space scanner may acquire space information by a person who holds the scanner and obtains the space information while walking. The dynamic space scanner may entail less limitations in places where the space information is obtained than the static space scanner, and may continuously acquire the space information.

The 360 degrees camera may be utilized as a static instant acquisition space scanner. The 360 degrees camera or omnidirectional camera is a camera having a 360-degree horizontal field of view, and may acquire image information by attaching the 360 degrees camera to an object such as a tripod, self-pi-stick, drone, etc.

Herein, the space information may be acquired using the dynamic space scanner and the static space scanner separately or complexly.

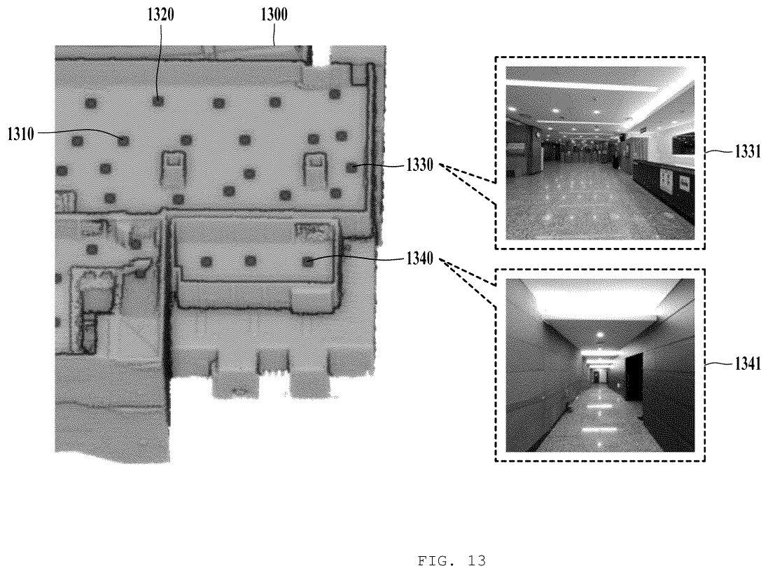

FIG. 13 is a figure explaining the static type scanning illustrated in FIGS. 12A to 12C, while FIG. 14 is a figure explaining the dynamic type scanning illustrated in FIGS. 12A to 12c.

Referring to FIG. 13, the space information acquisition may be performed by collecting sensor information acquired while rotating a static space scanner at fixed k−1 point 1310, and then, collecting sensor information while rotating the scanner at k point 1320 moved from the k−1 point 1310.

Further, the space information acquisition may be performed by collecting sensor information while moving the dynamic space scanner from k−1 point 1310 to k point 1320.

In the case of the static manner to acquire sensor information using the static space scanner, the space information alignment module 1160 shown in FIG. 11 may repeatedly execute a process of aligning scan information at k−1 point 1310 and scan information at k point 1320, which is smaller or equal to ‘n’ at k=2 to n times, in total ‘n’ numbers of scan spaces.

In this regard, the space information alignment module 1160 may generate the aligned sensor information through the probability-based coordinate relation prediction of raw sensor data and correction based on specific features.

For example, a plurality of alignment information for sensor information acquired at specific locations (1330, 1340) is converted with reference to a specific reference coordinate system, thereby enabling acquisition of consistent depth information 1300, as well as image information (1331, 1341) containing the position information in the target space.

In the case of the dynamic manner to acquire sensor information using the dynamic space scanner, the alignment may be generally done on a movement pathway 1410 at intervals (1411, 1413) in unit of millimeters or smaller. Accordingly, the number of repeated works for alignment may increase exponentially, and exact location information may be hardly determined by such alignment method to predict simple coordinate transformation.

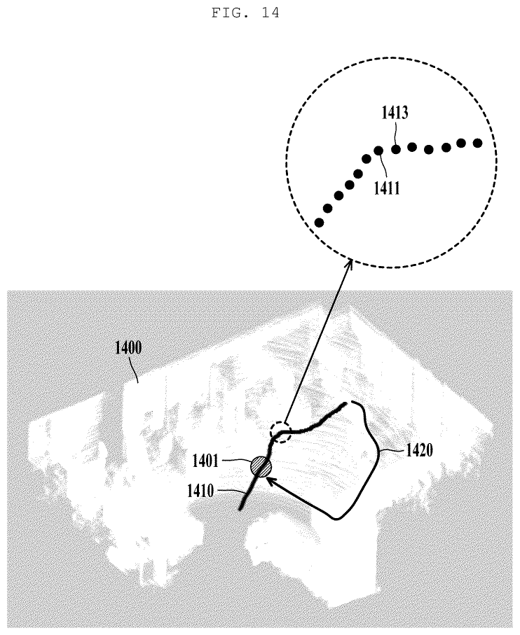

FIG. 15 illustrates an example of the estimation through probability distribution in FIG. 13 or 14, while FIG. 16 is a figure explaining an example of correction.

Referring to FIG. 15, a coordinate relation between the scan information collected at a first position 1411 and the scan information collected at a second position 1413 in the dynamic manner is represented by probability relation between the above two positions, wherein this process may be performed such that an average of the probability indicates the coordinate relation while a variation of the probability represents reliability between two coordinate relations.

At this time, the probability distribution used herein may be gaussian distribution and, in this case, a gaussian average may indicate the predicted coordinate relation 1510 while a gaussian variation may indicate the reliability of the predicted coordinate relation. The reliability of the predicted relation may be represented as an ellipse 1520 and it is interpreted that, as the ellipse is larger, the reliability of the predicted relation is lower.

When the sensor information is collected by the static type method, ‘alignment’, that is, a way of expecting a relatively large coordinate relation between two positions sufficiently far apart from each other may be applied.

On the contrary, when the sensor information is collected in the dynamic manner, as shown in FIG. 15, a method of estimating a relation between two positions, that is, prediction may be firstly carried out. The prediction of the relation between two positions may be conducted at all positions, otherwise, may be conducted by sampling a specific distance or at a specific period of time. However, even if such sampling is carried out, the prediction may be performed at markedly finer intervals as compared to two positions in the static method.

Thereafter, secondly, the estimated probability may be revised as shown in FIG. 16.

Referring to FIG. 16, when a specific feature 1630 is observed at k−1 point and then the same specific feature 1630 is observed at k point, the estimated probability is updated and the coordinate relation 1610 may be more correctly amended than the coordinate relation 1510 shown in FIG. 15.

Further, when updating the estimated probability using the specific feature 1630, the reliability 1620 may also be remarkably increased from the reliability 1520 shown in FIG. 15. Such specific feature-based correction may not only be implemented at k−1 and k times, but also be applied if the same specific feature is observed at all scan positions.

With regard to the space information collected in the dynamic manner, sampling may be performed. Further, as the estimation and correction are repeated at k=2 to k=n, there is a characteristic of flexibly changing the position until the final operation is completed, while the position in the alignment is fixed after arithmetic operation is finished one time.

For example, when visiting again a specific position 1401 shown in FIG. 14 through the scan movement pathway 1420 and scanning the same, correction at all positions during the period of time from the first visiting time to the second visiting time may proceed in the form of back-propagation, therefore, the estimation correction may cause a significant change in the entire position.

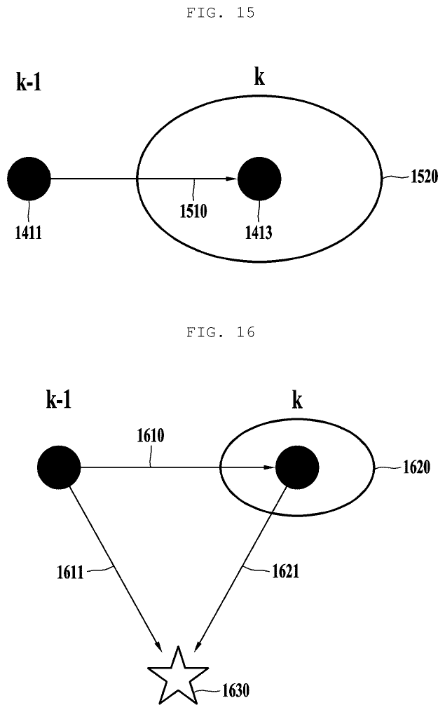

FIG. 17 is a figure explaining the configuration of a digital space model construction according to a fourth embodiment of the present invention.

Referring to FIG. 17, the automatic generation network module 1730 may conduct the same function as the automatic generation network module 110 shown in FIG. 1 or the automatic generation network module 410 shown in FIG. 4. Further, the space information database 1720 may conduct the same function as the space information database 120 shown in FIG. 1 or the space information database 420 shown in FIG. 4.

The embodiment shown in FIG. 17 is an example of illustrating that components of a digital space model can be modified after the digital space model is generated.

A modification request input module 1770 may receive modification information requesting modification of the component in the digital space model.

The automatic generation network module 1730 may modify or regenerate the digital space model based on the modification information.

At this time, a user may ask transformation of the structure schema or object schema. More specifically, it may be asked to change the type, size or attribute of the object or to replace textures of the wall or floor into new forms.

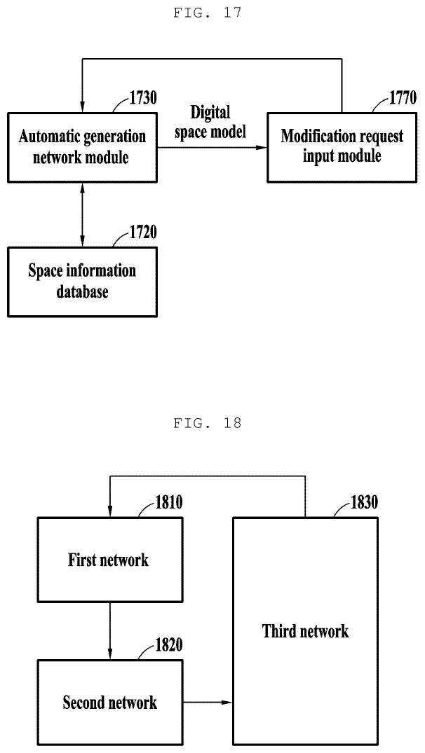

FIG. 18 is a figure explaining a process of constructing the digital space model generation network according to an embodiment of the present invention.

Referring to FIG. 18, a first network 1810 may be trained to receive raw sensor data including image information of a real space as input, and to generate a spatial schema encoded with physical features of the real space through descriptive expression.

A second network 1820 may be trained to select space information based on the spatial schema.

A third network 1830 may be trained to generate a digital space model based on the spatial schema and the selected space information. In this regard, the third network 1830 may be trained to classify the components included in the space information into a structure and an object, generate structure information related to the structure, and generate a digital space model based on the spatial schema of the structure information.

According to the embodiments of the present invention through FIGS. 1 to 18, the spatial schema is defined to have a role of medium and, after generating a structure through AI, the space may be re-constructed by selecting an object model.

For example, with regard to the geometry of a structure, a plurality of textures can be minutely aligned. At this time, on the basis of geometry and texture information, AI may regenerate the corresponding texture based on Cue of the texture. Further, since AI defines interrelation between the geometry and the texture by itself, it is possible to minutely align the geometry and texture.

With regard to space modeling according to the conventional art, a structure part with a simple geometric structure is under modeling by bottom-up approach to generate a model from the raw sensor data, while an object having a complex geometric structure is under modeling by top-down approach adopted from the existing database.

Such structure bottom-up and object top-down approaches enable realistic space reconstruction, however, may entail a limitation in that various detailed works, which are difficult to settle through automation such as the method for minutely aligning the plurality of textures into the geometry, require the handwork of a person.

According to the embodiments of the present invention, a perfectly automated realistic digital model can be constructed using a schema as a medium in such a way that automatically extractable spatial schema is described by bottom-up approach, and AI network re-constructs a space through top-down approach based on the extracted spatial schema.

The apparatus described above may be implemented as a hardware component, a software component, and/or a combination of hardware components and software components. For example, the apparatus and components described in the embodiments may be achieved using one or more general purpose or special purpose computers, such as, for example, a processor, a controller, an arithmetic logic unit (ALU), a digital signal processor, a microcomputer, a field programmable array (FPA), a programmable logic unit (PLU), a microprocessor, or any other device capable of executing and responding to instructions. The processing device may execute an operating system (OS) and one or more software applications executing on the operating system. In addition, the processing device may access, store, manipulate, process, and generate data in response to execution of the software. For ease of understanding, the processing apparatus may be described as being used singly, but those skilled in the art will recognize that the processing apparatus may include a plurality of processing elements and/or a plurality of types of processing elements. For example, the processing apparatus may include a plurality of processors or one processor and one controller. Other processing configurations, such as a parallel processor, are also possible.

The software may include computer programs, code, instructions, or a combination of one or more of the foregoing, configure the processing apparatus to operate as desired, or command the processing apparatus, either independently or collectively. In order to be interpreted by a processing device or to provide instructions or data to a processing device, the software and/or data may be embodied permanently or temporarily in any type of a machine, a component, a physical device, a virtual device, a computer storage medium or device, or a transmission signal wave. The software may be distributed over a networked computer system and stored or executed in a distributed manner. The software and data may be stored in one or more computer-readable recording media.

The methods according to the embodiments of the present disclosure may be implemented in the form of a program command that can be executed through various computer means and recorded in a computer-readable medium. The computer-readable medium can store program commands, data files, data structures or combinations thereof. The program commands recorded in the medium may be specially designed and configured for the present disclosure or be known to those skilled in the field of computer software. Examples of a computer-readable recording medium include magnetic media such as hard disks, floppy disks and magnetic tapes, optical media such as CD-ROMs and DVDs, magneto-optical media such as floptical disks, or hardware devices such as ROMS, RAMs and flash memories, which are specially configured to store and execute program commands. Examples of the program commands include machine language code created by a compiler and high-level language code executable by a computer using an interpreter and the like. The hardware devices described above may be configured to operate as one or more software modules to perform the operations of the embodiments, and vice versa.

Although the present disclosure has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

What is claimed is:

1. An apparatus for constructing a digital space model using a spatial schema as a medium, the apparatus comprising:
a spatial schema generation module configured to generate a spatial schema encoded as a descriptive expression relating to a target space, which is an object for constructing a digital space model;
a space information database configured to store spatial information including image data of the target space; and
an automatic generation network module configured to receive the spatial schema as input, and automatically construct a digital space model corresponding to the spatial schema based on the spatial schema and the spatial information stored in the space information database using a model trained to generate a digital space model.

2. The apparatus according to claim 1, wherein the target space is a physical space existing in the real world, and the digital space model is a three-dimensional digital space model capable of representing image information and depth information relating to the target space at an arbitrary pose.

3. The apparatus according to claim 1, wherein the spatial schema is information encoded based on the physical commonalities among components of the target space.

4. The apparatus according to claim 3, further comprising:
a structure/object classifier configured to classify the components of the target space into a structure and an object and to generate structure information related to the structure and object information related to the object,
wherein the spatial schema generation module is configured to: generate a structure schema encoded as a descriptive expression of the structure information based on at least one of a geometry of the structure information, a texture associated with the geometry, and the interrelation among the geometries; and generate an object schema encoded as a descriptive expression of the object information based on at least one of physical commonalities, interrelation and interdependency of the object information.

5. The apparatus according to claim 4, wherein the automatic generation network module receives the structure schema and the object schema as input, selects an object model in the space information database based on the object schema, and automatically constructs a digital space model based on the structure schema, the space information and the object model through the trained model.

6. The apparatus according to claim 5, further comprising:
a space information acquiring module configured to obtain raw sensor data including image information of a target space existing in the real world; and
a space information alignment module configured to align raw sensor data obtained in multiple positions based on a reference coordinate system so as to generate aligned sensor information.

7. The apparatus according to claim 6, wherein the raw sensor data is acquired: in a static manner, where the module rotates at fixed k−1 point and k point moved from k−1 point and acquires the data while rotating, or in a dynamic manner, where the module acquires the data while moving from k−1 point to k point,
wherein the space information alignment module generates the aligned sensor information through probability-based coordinate relation prediction of the raw sensor data and feature-based correction.

8. The apparatus according to claim 6, further comprising: a modification request input module to receive modification information requesting modification of a component in the digital space model,
wherein the automatic generation network module re-generates a digital space model based on the modification information.

9. The apparatus according to claim 5, wherein the automatic generation network module disposes the selected object model in the digital space model based on at least one of position information encoded in the object schema, interrelation information with surrounding environments and attribute information, wherein the attribute information of the object model is adjustable.

10. The apparatus according to claim 5, wherein, if an object model having a real-world identity to the object information encoded in the object schema that is not less than a standard value does not exist in the space information database, the automatic generation network module selects an object having high similarity to the object information or adds a model having high real-world identity from another database.

11. The apparatus according to claim 1, wherein the model trained to generate the digital space model is a large-scale space model trained through:
a first network generation process that receives raw sensor data including image information of a real space as input and learns to generate a spatial schema encoded with physical features of the real space through descriptive expression;
a second network generation process that learns to select space information based on the spatial schema; and
a third network generation process that learns to generate a digital space model based on the spatial schema and the selected space information.

12. The apparatus according to claim 11, wherein the third network learns to classify the components included in the space information into a structure and an object, generate structure information related to the structure, and generate a digital space model based on the spatial schema to the structure information.

13. A method for constructing a digital space model using a spatial schema as a medium, the method comprising:
generating a spatial schema encoded as a descriptive expression of a target space, which is an object for constructing a digital space model;
constructing space information database storing space information including image data for the target space;
receiving the spatial schema as input; and
automatically constructing a digital space model corresponding to the spatial schema, based on the spatial schema and the space information stored in the space information database using a model trained to generate the digital space model.

14. A method for constructing a three-dimensional digital space model that can represent image information and depth information of a target space at any arbitrary pose, wherein the target space physically exists in the real world, the method comprising:
classifying components in the target space into a structure and an object, and generating structure information related to the structure and object information related to the object;
generating a structure schema encoded as a descriptive expression of the structure information based on at least one of physical commonalities, interrelation and interdependency of the structure information;
generating an object schema encoded as a descriptive expression of the object information based on at least one of physical commonalities, interrelation and interdependency of the object information;
receiving the structure schema and the object schema as input, and selecting an object model in the space information database based on the object schema; and
receiving the structure schema and the object model as input, and automatically constructing a digital space model of the target space using a model trained to generate the digital space model.

15. The method according to claim 14, further comprising:
acquiring raw sensor data including image information of a target space existing in the real world; and
aligning the raw sensor data acquired at a plurality of positions based on a reference coordinate system to generate aligned sensor information,
wherein the aligned sensor information includes components of the target space.
